(19) United States
(12) Patent Application Publication
(10) Pub. No.: US 2011/0254078 A1
(43) Pub. Date: Oct. 20, 2011

(54) METHOD FOR DEPOSITING SILICON NITRIDE FILM, COMPUTER-READABLE STORAGE MEDIUM, AND PLASMA CVD DEVICE

(75) Inventors: Minoru HONDA, Amagasaki-shi (JP); Masayuki KOHNO, Amagasaki-shi (JP)

(73) Assignee: TOKYO ELECTRON LIMITED, Tokyo (JP)

(21) Appl. No.: 13/164,366

(22) Filed: Jun. 20, 2011

Related U.S. Application Data
(63) Continuation-in-part of application No. 13/121,617.

(30) Foreign Application Priority Data
Sep. 30, 2008 (JP) 2008-253932

(51) Int. Cl. H01L 29/792; C23C 16/511; H01L 21/318; B05C 11/00

(52) U.S. Cl. 257/324; 118/697; 118/723 AN; 118/719; 438/791; 257/E29.309; 257/E21.293

(57) ABSTRACT

Provided is a method for depositing a silicon nitride film in a plasma CVD device which introduces microwaves into a process chamber by a planar antenna having a plurality of apertures, and the method including setting the pressure in the process chamber within a range from 10 Pa to 133.3 Pa and performing plasma CVD by using film formation gas including a silicon containing compound gas and a nitrogen gas while applying an RF bias to the wafer by supplying high-frequency power with an output density within a range from 0.009 W/cm² to 0.64 W/cm² per unit area of a wafer from a high frequency power supply to an electrode in a holding stage on which the wafer is arranged.

### CROSS-REFERENCE TO RELATED APPLICATION

This is a continuation-in-part application of U.S. application Ser. No. 13/121,617, filed on Mar. 29, 2011, which claims the benefit of Japanese Patent Application No. 2008-253932, filed on Sep. 30, 2008 in the Japan Patent Office, the disclosure of which is incorporated herein in its entirety by reference.

### TECHNICAL FIELD

The present invention relates to a method for depositing a silicon nitride film, a computer-readable storage medium having recorded thereon, and a plasma CVD device used in the method.

### BACKGROUND ART

Currently, from among non-volatile semiconductor memory devices represented by an EEPROM (Electrically Erasable and Programmable ROM), which may be electrically reprogrammed, there are non-volatile semiconductor memory devices having a SONOS (Silicon-Oxide-Nitride-Oxide-Silicon) type stacked structure or a MONOS (Metal-Oxide-Nitride-Oxide-Silicon) type stacked structure. In a non-volatile semiconductor memory device of such a type, silicon nitride film of one layer or more layers sandwiched between silicon dioxide films hold(s) data as a charge trapping region. In other words, the non-volatile semiconductor memory device is reprogrammed either by retaining data by implanting electrons into a silicon nitride film in a charge trapping region or deleting data by removing electrons accumulated in the silicon nitride film, by applying a voltage between a semiconductor substrate (silicon) and a control gate electrode (silicon or metal). In the non-volatile semiconductor memory device, it is thought that data writing characteristics are related to ease of implanting electrons into a silicon nitride film, which is a charge trapping region, and more particularly, related to the charge trapping center (trap) existing in a silicon nitride film.

As a technique related to a non-volatile semiconductor memory device, patent reference 1 discloses installment of a transition layer with high Si amount between a silicon nitride film and a top oxide film to increase trapping density of the interface between the silicon nitride film and the top oxide film.

### PRIOR ART REFERENCE

### Patent Reference

(Patent Reference 1) Japanese Laid-Open Patent Publication No. hei 5-145078 (e.g., Paragraph 0015, or the like)

### DISCLOSURE OF THE INVENTION

### Technical Problem

Along with recently high integrations of semiconductor devices, element structures of non-volatile semiconductor memory devices are rapidly miniaturized. To miniaturize a non-volatile semiconductor memory device, it is necessary to improve data writing performance by increasing a number of traps in a silicon nitride film, which is a charge trapping layer, in an individual non-volatile semiconductor memory device.

However, it has been technically difficult to control formation of traps in a silicon nitride film during formation of the silicon nitride film by using a film formation method including a depressurized CVD method or a thermal CVD method. Furthermore, in the case of a plasma CVD method, in most cases, it has been aimed to form a silicon nitride film, which is dense, has a small number of defects, and is used as a hard mask or a stopper film during etching. However, it has been thought that, in a plasma CVD method, it is possible to form a large number of traps within a formed silicon nitride film by strengthening ionicity of plasma by setting process pressure inside a process chamber to high vacuum state (e.g., less than or equal to 3 Pa). However, to maintain the inside of a process chamber to a high vacuum state, for example, an exhauster of a high performance is necessary, or a vacuum sealing technique and a pressure container that may withstand the high vacuum state are necessary. In other words, device loads increase, and thus costs increase as well. Furthermore, in the high vacuum state, plasma energy increases, and thus sputtering with respect to parts in a process chamber is strengthened. Also, in an aspect of process, problems including increased risk of being polluted by particles or the like, decreased coverage performance during formation of a silicon nitride film, or the like occur. Furthermore, it has not been possible to use a silicon nitride film formed by using a conventional plasma CVD method as a charge trapping layer, because distribution of traps in the silicon nitride film are not uniform.

To resolve the problems stated above, the present invention provides a method of forming a silicon nitride film, which has a large number of traps therein and may be used as a charge trapping layer, by using a plasma CVD method. Furthermore, the present invention also provides a method of forming a film by stacking silicon nitride films having different numbers of traps with the silicon nitride films by using a plasma CVD method.

### Technical Solution

According to an aspect of the present invention, there is provided a method for depositing a silicon nitride film on an object to be processed by using a plasma CVD method by using a plasma CVD device that generates plasma by introducing microwaves into a process chamber by using a planar antenna having a plurality of apertures, the method including forming a silicon nitride film by setting a pressure inside the process chamber in a range from 10 Pa to 133.3 Pa and by performing plasma CVD by using film formation gases including a silicon containing compound gas and a nitrogen gas while applying a high frequency bias to the object to be processed by supplying high frequency power with an output density in a range from 0.009 W/cm² to 0.64 W/cm² per unit area of the object to be processed to an electrode of a holding stage, on which the object to be processed is arranged.

According to another aspect of the present invention, there is provided a method for depositing a silicon nitride film by stacking silicon nitride films on an object to be processed by using a plasma CVD method by using a plasma CVD device that generates plasma by introducing microwaves into a process chamber by using a planar antenna having a plurality of apertures, the method including a first operation for forming a silicon nitride film by setting a pressure inside the process chamber in a range from 10 Pa to 133.3 Pa, and performing plasma CVD by using film formation gases including a silicon containing compound gas and a nitrogen gas while applying a high frequency bias to the object to be processed by supplying high frequency power with an output density in a range from 0.009 W/cm² to 0.64 W/cm² per unit area of the object to be processed to an electrode of a holding stage, on which the object to be processed is arranged; and a second operation for forming a silicon nitride film that has a small number of traps as compared to the silicon nitride film formed in the first operation, under the same set pressure as the first operation, by performing plasma CVD by using film formation gases including a silicon containing compound gas and a nitrogen gas by not applying high frequency power to the electrode of the holding stage or by applying a high frequency bias to the object to be processed by supplying high frequency power with an output density different from the output density of the first operation.

The first operation and the second operation may be repeatedly performed.

According to another aspect of the present invention, there is provided a computer-readable storage medium having recorded thereon a control program to be operated on a computer, wherein, when a silicon nitride film is being formed on an object to be processed by using a plasma CVD method by using a plasma CVD device that generates plasma by introducing microwaves into a process chamber by using a planar antenna having a plurality of apertures, the control program enables the computer to control the plasma CVD device to perform plasma CVD by using film formation gases including a silicon containing compound gas and a nitrogen gas under a process pressure in a range from 10 Pa to 133.3 Pa by applying high frequency bias to the object to be processed by supplying high frequency power with an output density in a range from 0.009 W/cm² to 0.64 W/cm² per unit area of the object to be processed to an electrode of a holding stage, on which the object to be processed is arranged.

According to another aspect of the present invention, there is provided a plasma CVD device that forms a silicon nitride film on an object to be processed by using a plasma CVD method, the plasma CVD device including a process chamber which accommodates the object to be processed and has an opening on a top of the process chamber; a holding stage that is arranged inside the process chamber and on which the object to be processed is arranged; an electrode that is installed in the holding stage and applies high frequency power to the object to be processed; a high frequency power supply connected to the electrode; a dielectric member which closes the opening of the process chamber; a planar antenna which is installed on the dielectric member and has a plurality of apertures for introducing microwaves into the process chamber; a gas introduction unit which is connected to a gas supply apparatus for supplying a film formation gases including a silicon containing compound gas and an nitrogen gas into the process chamber; an exhauster which depressurizes and exhausts an inside of the process chamber; and a control unit that controls plasma CVD to be performed in the process chamber under a process pressure in a range from 10 Pa to 133.3 Pa by supplying the film formation gases including the silicon containing compound gas and the nitrogen gas into the process chamber while applying a high frequency bias to the object to be processed by supplying high frequency power with an output density in a range from 0.009 W/cm² to 0.64 W/cm² per unit area of the object to be processed from the high frequency power supply to the electrode.

### Advantageous Effects

By using a method for depositing a silicon nitride film according to the present invention, a silicon nitride film having a large number of traps therein may be formed by applying high frequency power to a holding stage, on which an object to be processed is arranged, and performing plasma CVD thereon under a process pressure in a range from 10 Pa to 133.3 Pa inside a process chamber, by using a plasma CVD device that generates plasma by introducing microwaves into a process chamber by using a planar antenna having a plurality of apertures. The method of the present invention provides advantages of reduced device loads and a reduced pollution risk as compared to film formation in a high vacuum state less than or equal to 3 Pa. Also, fine coverage performance in terms of formation of a silicon nitride film may be maintained. Furthermore, a silicon nitride film formed by using the method of the present invention has uniformly distributed traps therein, and thus is suitable to be used as a charge trapping layer.

Also, by using a method for depositing a silicon nitride film according to the present invention, silicon nitride films having different numbers of traps therein may be alternately stacked at ease by simply switching ON/OFF of high frequency power applied to a holding stage, and thus silicon nitride films formed by using the method of the present invention may be applied to a semiconductor memory device with excellent data writing characteristics.

### BRIEF DESCRIPTION OF THE DRAWINGS

FIG. 1 is a schematic cross-sectional view showing an example of a plasma CVD device suitable for formation of a silicon nitride film;

FIG. 2 is a diagram showing a structure of a planar antenna;

FIG. 3 is a diagram for explaining a structure of a control unit;

FIG. 4 is a diagram showing example processes of a method of forming a silicon nitride film, according to a first embodiment of the present invention;

FIG. 5 is a diagram for explaining a method of measuring Vfb hysteresis, where FIG. 5A is a schematic descriptive diagram of a capacitor used for the measurement, and FIG. 5B is a diagram showing a CV curve;

FIG. 6 is a graph showing refractive index of a silicon nitride film, wet etching rate of the silicon nitride film, and measured Vfb hysteresis versus RF bias power used during formation of the silicon nitride film;

FIG. 7 is a graph showing a result of measuring Vfb hysteresis of a silicon nitride film versus a flow rate of Ar gas during formation of the silicon nitride film;

FIG. 8 is a diagram showing example processes of a method for forming a silicon nitride film stacked structure, according to a second embodiment of the present invention; and

FIG. 9 is a view for explaining a schematic structure of a MOS type semiconductor memory device to which the method of the present invention is applicable.

### BEST MODE FOR CARRYING OUT THE INVENTION

### First Embodiment

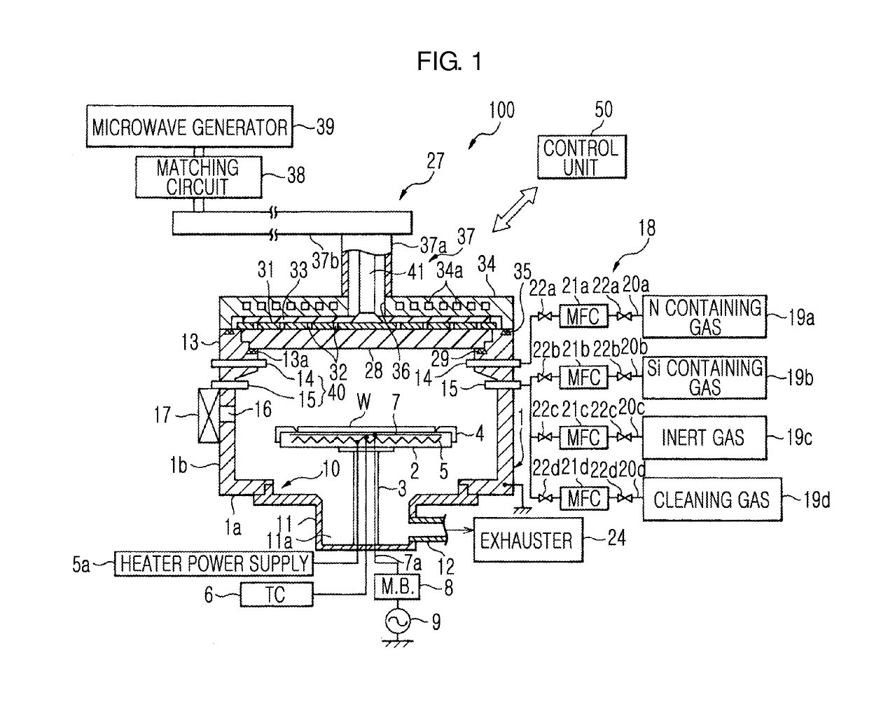

Hereinafter, the present invention will be described in detail by explaining exemplary embodiments of the invention with reference to the attached drawings. FIG. 1 is a schematic cross-sectional view showing a schematic structure of a plasma CVD device 100 used in a method for depositing a silicon nitride film of the present invention.

The plasma CVD device 100 is configured as a RLSA (Radial Line Slot Antenna) microwave plasma process apparatus that can generate microwave excitation plasma having a high density and a low electron temperature, by generating plasma by introducing microwaves into a process chamber by using a planar antenna including a plurality of apertures each having a slot shape, specifically a RLSA. The plasma CVD device 100 is able to perform a process using plasma having a low electron temperature from 0.7 eV to 2 eV, and a plasma density from 1×10¹⁰/cm³ to 5×10¹²/cm³. Accordingly, the plasma CVD device 100 may be very suitably used to form a silicon nitride film by using plasma CVD while manufacturing various semiconductor devices.

Important elements of the plasma CVD device 100 include an airtight process chamber 1, gas introduction units 14 and 15 connected via gas introduction pipes to a gas supply apparatus 18 for supplying a gas into the process chamber 1, an exhaust apparatus including an exhauster 24 for depressurizing and exhausting an inside of the process chamber 1, a microwave introduction apparatus 27 disposed above the process chamber 1 and for introducing microwaves into the process chamber 1, and a control unit 50 for controlling each element of the plasma CVD device 100. Also, in the embodiment of FIG. 1, the gas supply apparatus 18 is integrally installed to the plasma CVD device 100, but may not be integrally installed. The gas supply apparatus 18 may be installed outside the plasma CVD device 100.

The process chamber 1 is a grounded container having an approximately cylindrical shape. Alternatively, the process chamber 1 may be a container having a prismatic shape. The process chamber 1 has a bottom wall 1a and a side wall 1b that are formed of a material such as aluminum or the like.

A holding stage 2 for horizontally supporting a silicon wafer (hereinafter, simply referred to as a “wafer”) W constituting an object to be processed is installed inside the process chamber 1. The holding stage 2 is formed of a material having a high thermal conductivity, for example, a ceramic, such as AlN or the like. The holding stage 2 is supported by a supporting member 3 having a cylindrical shape extending upward from a bottom center of an exhaust chamber 11 and is fixed to the bottom. The supporting member 3 may be formed of a ceramic, such as AlN or the like.

A cover ring 4 for covering an outer edge portion of the holding stage 2 and guiding the wafer W is installed on the holding stage 2. The cover ring 4 is a ring-shaped member formed of a material such as quartz, AlN, Al₂O₃, SiN, or the like.

A resistance heating type heater 5 is embedded in the holding stage 2, to serve as a temperature adjusting apparatus. The heater 5 heats the holding stage 2 by receiving power from a heater power supply 5a, and the wafer W constituting a substrate to be processed is uniformly heated by heat from the holding stage 2. Furthermore, although not shown, a nozzle filter for cutting high frequency noise originated from high frequency power supplied to an electrode 7 while a temperature is controlled by supplying power from the heater power supply 5a to the heater 5 is installed.

A thermocouple (TC) 6 is disposed at the holding stage 2. A temperature is measured by using the thermocouple 6, and thus a heating temperature of the wafer W is controllable, for example, in the range from room temperature to 900° C.

Also, the holding stage 2 includes wafer support pins (not shown) for supporting and elevating the wafer W. Each wafer support pin is installed to be able to protrude and retract with respect to a surface of the holding stage 2.

Also, the electrode 7 is embedded in a surface of the holding stage 2. The electrode 7 is arranged between the heater 5 and the surface of the holding stage 2. A high frequency power supply 9 for bias application is connected to the electrode 7 by a power feeding line 7a via a matching box (MB) 8. The MB 8 is configured to be able to apply a high frequency bias (an RF bias) to a wafer W constituting a substrate by supplying high frequency power from the high frequency power supply 9 to the electrode 7. A material of the electrode 7 may be a material having a thermal expansion coefficient equivalent to that of a ceramic, which is a material of the holding stage 2, such as AlN or the like. For example, a conductive material, such as molybdenum, tungsten, or the like may be used as the material of the electrode 7. The electrode 7 is formed to a mesh shape, a lattice shape, a spiral shape, or the like. The electrode 7 may be formed to have a size at least equal to or larger than an object to be processed.

A circular opening 10 is formed around a center of the bottom wall 1a of the process chamber 1. The exhaust chamber 11, which protrudes downward from the bottom wall 1a and communicates with the opening 10, is continuously installed on the bottom wall 1a. The exhaust chamber 11 is connected to an exhaust pipe 12, and is connected to the exhauster 24 through the exhaust pipe 12.

A ring-shaped plate 13 functioning as a cover body (lid) for opening and closing the process chamber 1 is disposed on an upper end of the side wall 1b forming the process chamber 1. A bottom inner circumference of the plate 13 protrudes inward (toward a space inside the process chamber) to form a ring-shaped supporter 13a.

A gas introduction unit 40 is disposed at the plate 13. The gas introduction unit 40 includes a first gas introduction unit 14 having a first gas introduction hole. Furthermore, a second gas introduction unit 15 having a second gas introduction hole is formed in the side wall 1b of the process chamber 1. In other words, the first gas introduction unit 14 and the second gas introduction unit 15 are installed in two stages consist of a top stage and a bottom stage. The first gas introduction unit 14 and the second gas introduction unit 15 are connected to the gas supply apparatus 18, which supplies a raw material gas for film formation or a gas for plasma excitation. Alternatively, the first gas introduction unit 14 and the second gas introduction unit 15 may each have a nozzle shape or a shower head shape. Alternatively, the first and second gas introduction units 14 and 15 may be installed as a single shower head. Alternatively, the first gas introduction unit 14 and the second gas introduction unit 15 may be installed together to the side wall 1b of the process chamber 1.

A transfer hole 16 for transferring the wafer W between the plasma CVD device 100 and a transfer chamber (not shown) adjacent to the plasma CVD device 100, and a gate valve 17 for opening and closing the transfer hole 16 are installed on the side wall 1b of the process chamber 1.

The gas supply apparatus 18 includes, for example, a nitrogen containing gas (N containing gas) supply source 19a and a silicon containing compound gas (Si containing gas) supply source 19b that supply film formation gases, an inert gas supply source 19c that supplies an inert gas for plasma generation, and a cleaning gas supply source 19d that supplies a cleaning gas used for cleaning the inside of the process chamber 1. The N containing gas supply source 19a is connected to the first gas introduction unit 14. Also, the Si containing compound gas supply source 19b, the inert gas supply source 19c, and the cleaning gas supply source 19d are connected to the second gas introduction unit 15. Also, the gas supply apparatus 18 may separately include, for example, a purge gas supply source or the like used to replace an atmosphere inside the process chamber, as another gas supply source (not shown). Alternatively, the inert gas supply source 19c may be used as a purge gas supply source.

In the present invention, a nitrogen gas (N₂) is used as the nitrogen containing gas, which is a raw gas for film formation. Also, for example, SiₙH₂ₙ₊₂, such as silane (SiH₄), disilane (Si₂H₆), trisilane (Si₃H₈), etc., TSA (trisilylamine), or the like may be used as the Si containing compound gas, which is another raw material gas for film formation. Particularly, disilane (Si₂H₆) is preferable. In other words, for the purpose of controlling a number of traps in a silicon nitride film, a combination of a nitrogen gas and disilane is preferable as a raw gas for film formation. Also, for example, an N₂ gas or a rare gas may be used as the inert gas. The rare gas helps generation of stable plasma, as a plasma excitation gas, and for example, an Ar gas, a Kr gas, a Xe gas, a He gas, or the like may be used as the rare gas. Also, for example, a ClF₃ gas, a NF₃ gas, a HCl gas, a F₂ gas, or the like may be used as the cleaning gas. Particularly, the NF₃ gas is preferable.

The nitrogen containing gas reaches the first gas introduction unit 14 from the N containing gas supply source 19a of the gas supply apparatus 18 through a gas line 20a, and is introduced into the process chamber 1 from the first gas introduction unit 14. Meanwhile, the Si containing compound gas, the inert gas, and the cleaning gas reach the second gas introduction unit 15 respectively from the Si containing compound gas supply source 19b, the inert gas supply source 19c, and the cleaning gas supply source 19d respectively through the gas lines 20b through 20d, and are introduced into the process chamber 1 from the second gas introduction unit 15. Mass flow controllers 21a through 21d and opening and closing valves 22a through 22d respectively in front and behind the mass flow controllers 21a through 21d are respectively installed in the gas lines 20a through 20d respectively connected to the gas supply sources. A switch of supplied gases, a flow rate, and the like are controllable by such a structure of the gas supply apparatus 18. Here, the inert gas for plasma excitation, such as Ar or the like, is a predetermined gas, and does not have to be supplied at the same time as with a raw gas for film formation.

The exhauster 24 constituting an exhaust apparatus includes a high speed vacuum pump, such as a turbomolecular pump or the like. As described above, the exhauster 24 is connected to the exhaust chamber 11 of the process chamber 1 through the exhaust pipe 12. By operating the exhauster 24, a gas inside the process chamber 1 uniformly flows into a space 11a inside the exhaust chamber 11, and is then exhausted from the space 11a to an exterior through the exhaust pipe 12. Accordingly, it is possible to depressurize the inside of the process chamber 1, for example, up to 0.133 Pa, at a high speed.

A structure of the microwave introduction apparatus 27 will now be described. Important elements of the microwave introduction apparatus 27 include a penetration plate 28, a planar antenna 31, a wavelength-shortening material 33, a cover member 34, a waveguide 37, and a microwave generator 39.

The penetration plate 28 as a dielectric member is arranged on the supporter 13a protruding in a long manner toward an inner circumference of the plate 13. The penetration plate 28 is formed of a dielectric material through which microwaves penetrate, for example, a ceramic such as quartz, Al₂O₃, AlN, or the like. Particularly, in a case of a plasma CVD device, a ceramic such as Al₂O₃, AlN, or the like may be used. A space between the penetration plate 28 and the supporter 13a is sealed air tight by disposing a seal member 29. Accordingly, the process chamber 1 is held air tight.

The planar antenna 31 is installed above the penetration plate 28 to face the holding stage 2. The planar antenna 31 has a disk shape. However, a shape of the planar antenna 31 is not limited to the disk shape, and, for example, the planar antenna 31 may have a rectangular plate shape. The planar antenna 31 is engaged with a top end of the plate 13.

The planar antenna 31 is formed of, for example, a plate such as a copper plate, a nickel plate, a SUS plate, or an aluminum plate, which has a surface coated with gold or silver. The planar antenna 31 includes a plurality of microwave radiation holes 32 each having a slot shape and for radiating microwaves. The microwave radiation holes 32 penetrate and are arranged through the planar antenna 31 in a predetermined pattern.

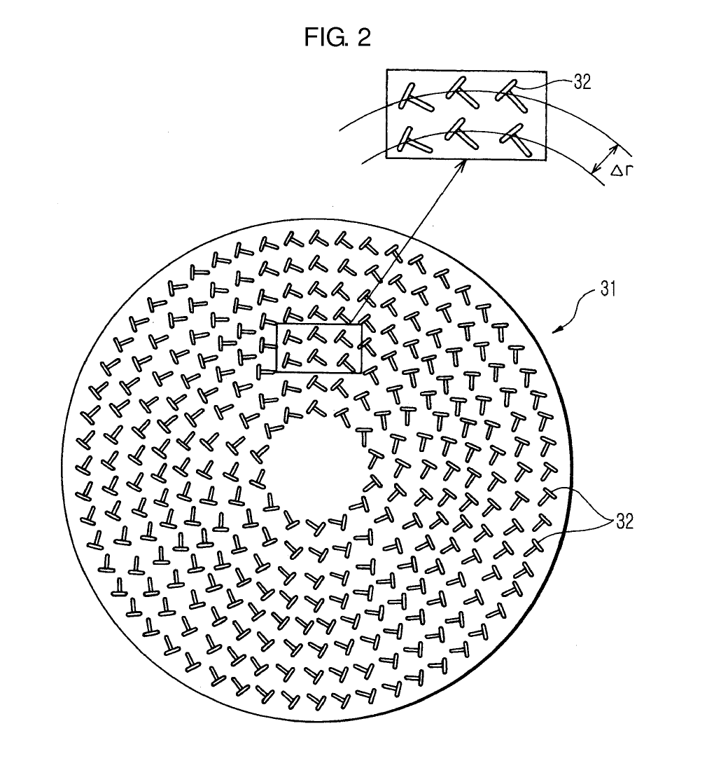

Each microwave radiation hole 32 has, for example, a thin and long rectangular shape (slot shape) as shown in FIG. 2, and two adjacent microwave radiation holes form a pair. The adjacent microwave radiation holes 32 are typically arranged in a “L” shape. Also, the microwave radiation holes 32 disposed after combining in such a predetermined shape (for example, an “L” shape) are also arranged overall in a concentric shape.

Lengths or arranged intervals of the microwave radiation holes 32 are determined according to a wavelength (λg) of microwaves. For example, an interval of the microwave radiation holes 32 is arranged to be from

$$\frac{λ g}{4}$$

to λg. In FIG. 2, an interval between the adjacent microwave radiation holes 32 arranged in a concentric shape is Δr. Alternatively, a shape of microwave radiation hole 32 may vary and be, for example, a circular shape, an arc shape, or the like. Also, an arrangement of the microwave radiation holes 32 is not specifically limited, and may be, for example, a spiral shape, a radial shape or the like aside from the concentric shape.

The wavelength-shortening material 33, having a dielectric constant higher than vacuum, e.g., quartz, Al₂O₃, AlN, resin, or the like, is installed on a top surface of the planar antenna 31. The wavelength-shortening material 33 shortens a wavelength of microwaves in order to adjust plasma, since the wavelength of the microwaves lengthens in a vacuum.

Also, the planar antenna 31 and the penetration plate 28, and the wavelength-shortening material 33 and the planar antenna 31 may contact or be separated from each other, but preferably contact each other.

The cover member 34 is formed on an upper portion of the plate 13 so as to cover the planar antenna 31 and the wavelength-shortening material 33. The cover member 34 may be formed of, for example, a metal material such as aluminum, stainless steel, or the like. The plate 13 and the cover member 34 are sealed by a seal member 35. A cooling water path 34a may be formed inside the cover member 34. Cooling water flows through the cooling water path 34a, thereby cooling the cover member 34, the wavelength-shortening material 33, the planar antenna 31, and the penetration plate 28. Also, the cover member 34 is grounded.

An opening 36 is formed on a center of a top wall (ceiling portion) of the cover member 34, and the waveguide 37 is connected to the opening 36. The microwave generator 39 for generating microwaves is connected to another end of the waveguide 37 through a matching circuit 38.

The waveguide 37 includes a coaxial waveguide 37a having a circular cross-section and extending upward from the opening 36 of the cover member 34, and a rectangular waveguide 37b connected to an upper end of the coaxial waveguide 37a and extending in a horizontal direction.

An inner conductor 41 extends in a center of the coaxial waveguide 37a. A bottom portion of the inner conductor 41 is connected and fixed to a center of the planar antenna 31. According to such a structure, microwaves are efficiently uniformly propagated in a radial shape to the planar antenna 31 through the inner conductor 41 of the coaxial waveguide 37a.

By using the microwave introduction apparatus 27 having the above structure, microwaves generated in the microwave generator 39 are propagated to the planar antenna 31 through the waveguide 37, and then are introduced into the process chamber 1 through the penetration plate 28. Also, a frequency of the microwaves may be, for example, 2.45 GHz, and may be 8.35 GHz, 1.98 GHz, or the like, aside from 2.45 GHz.

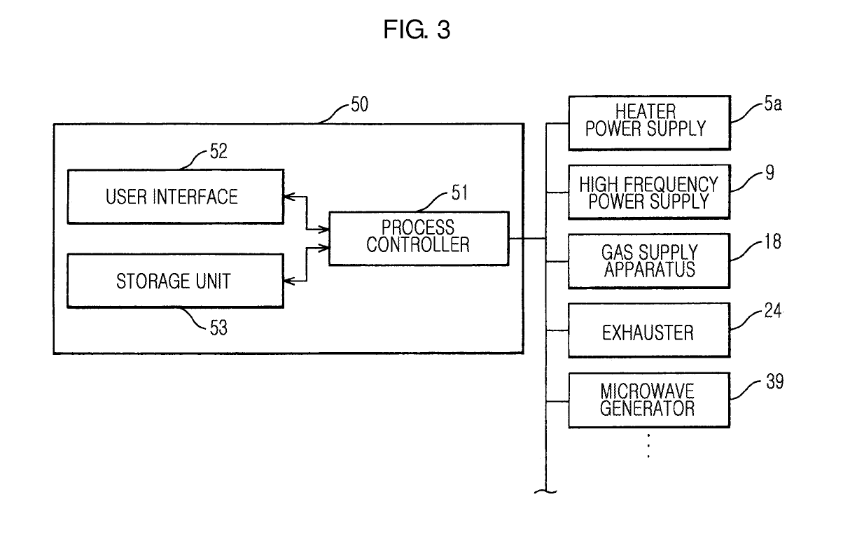

Each element of the plasma CVD device 100 is connected to and controlled by the control unit 50. The control unit 50 includes a computer, and, for example, includes a process controller 51 having a CPU, and a user interface 52 and a storage unit 53 connected to the process controller 51, as shown in FIG. 3. The process controller 51 is a control unit that generally controls elements of the plasma CVD device 100 that are related to, for example, process conditions, such as a temperature, a pressure, a gas flow rate, a microwave output, high frequency power for bias application, etc. (for example, the heater power supply 5a, the high frequency power supply 9, the gas supply apparatus 18, the exhauster 24, the microwave generator 39, etc.).

The user interface 52 includes a keyboard for an operation manager to perform input manipulation or the like of a command to manage the plasma CVD device 100, a display for visually displaying an operation situation of the plasma CVD device 100, and the like. Also, the storage unit 53 stores a control program (software) for executing various processes in the plasma CVD device 100 under a control of the process controller 51, or a recipe on which process condition data, etc. is recorded.

Also, if required, a predetermined recipe is called from the storage unit 53 via instructions from the user interface 52 or the like and executed in the process controller 51, thereby performing a desired process in the process chamber 1 of the plasma CVD device 100 under a control of the process controller 51. The control program and the recipe recording process condition data or the like may be stored in a computer readable storage medium, such as a CD-ROM, a hard disk, a flexible disk, a flash memory, a DVD, a Blu-ray disk, or the like, and accessed therefrom. Alternatively, the control program, the recipe, such as the process condition data, or the like may be frequently received from another device, for example, through an exclusive line, and accessed online.

Next, a deposition process of a silicon nitride film using a plasma CVD method using the RLSA type plasma CVD device 100 will be described. First, the gate valve 17 is opened and the wafer W is transferred into the process chamber 1 through the transfer hole 16 and placed on the holding stage 2. Then, while depressurizing and exhausting the inside of the process chamber 1, the nitrogen containing gas, the silicon containing compound gas, and the inert gas are introduced into the process chamber 1 respectively from the N containing gas supply source 19a, the Si containing compound gas supply source 19b, and the inert gas supply source 19c of the gas supply apparatus 18 respectively through the first gas introduction unit 14 and the second gas introduction unit 15, at predetermined flow rates. Also, the inside of the process chamber 1 is adjusted to a predetermined pressure.

Then, microwaves of a predetermined frequency, for example, 2.45 GHz, generated in the microwave generator 39 are led to the waveguide 37 through the matching circuit 38. The microwaves led to the waveguide 37 sequentially pass through the rectangular waveguide 37b and the coaxial waveguide 37a, and are supplied to the planar antenna 31 through the inner conductor 41. In other words, the microwaves are propagated toward the planar antenna 31 through the coaxial waveguide 37a. Also, the microwaves are radiated to a space above the wafer W in the process chamber 1 from the microwave radiation holes 32 each having a slot shape of the planar antenna 31 through the penetration plate 28. Here, a microwave output as output density per area of the penetration plate 28 in a portion through which microwaves penetrate may be in the range from 0.25 W/cm² to 2.56 W/cm². The microwave output may be selected to be an output density within the range, for example, from 500 W to 5000 W, according to a purpose.

An electric field is formed inside the process chamber 1 by the microwaves radiated to the process chamber 1 from the planar antenna 31 through the penetration plate 28, and thus the nitrogen containing gas and the silicon containing compound gas are each plasmatized. Then, a raw gas is efficiently dissociated in the plasma, and a thin film of silicon nitride (SiN) is deposited by a reaction of active species of SiₚH_{q}, SiH_{q}, NH_{q}, N, or the like (here, p and q indicate arbitrary numbers). After forming the silicon nitride film on a substrate, silicon nitride films deposited in the chamber are cleaned by supplying a ClF₃ gas as a cleaning gas into the chamber 1 and cleaning the chamber 1 by using heat at a temperature from 100° C. to 500° C., and preferably from 200° C. to 300° C. Alternatively, when an NF₃ gas is used as a cleaning gas, plasma is generated at a temperature from room temperature to 300° C. to perform the cleaning.

Also, while a plasma CVD process is being performed, an RF bias is applied to the wafer W by supplying high frequency power having a predetermined frequency and magnitude from the high frequency power supply 9 to the electrode 7 of the holding stage 2. Since a low electron temperature of plasma may be maintained in the plasma CVD device 100, no damage is inflicted to a film. Also, since molecules of a film formation gas are easily dissociated by high-density plasma, reactions are accelerated. Furthermore, application of an RF bias in a suitable range causes ions in plasma to be attracted by the wafer W, and thus a density of a silicon nitride film is improved and a number of traps therein may increase.

A frequency of an RF bias supplied from the high frequency power supply 9 may be in the range from 400 kHz to 60 MHz, for example, and preferably from 450 kHz to 20 MHz. In terms of output density per area of the wafer W, the RF bias may be applied in the range from 0.009 W/cm² to 0.64 W/cm², and preferably from 0.016 W/cm² to 0.095 W/cm². Furthermore, power of the RF bias may be in the range from 3 W to 200 W. Preferably, the RF bias power may be supplied to an electrode to be the output density within the range from 5 W to 20 W, and thus the RF bias may be applied.

The above conditions are stored as a recipe in the storage unit 53 of the control unit 50. Also, the process controller 51 reads the recipe, and transmits a control signal to each element of the plasma CVD device 100, for example, the gas supply apparatus 18, the exhauster 24, the microwave generator 39, the heater power supply 5a, the high frequency power supply 9, etc., thereby realizing a plasma CVD process performed under a desired condition.

Furthermore, the plasma CVD device 100 having the configuration stated above may control a number of traps existing in a formed silicon nitride film to uniformly increase, by maintaining a constant pressure condition in a plasma CVD process during formation of the silicon nitride film and supplying RF bias power from the high frequency power supply 9 to the electrode 7 of the holding stage 2 in the range of output densities from 0.009 W/cm² to 0.64 W/cm².

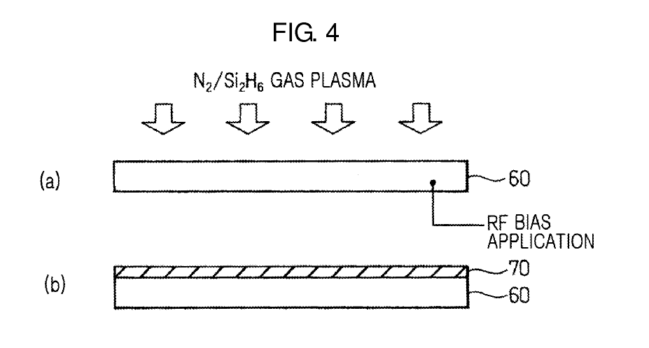

FIG. 4 is a process diagram showing processes of forming a silicon nitride film performed by the plasma CVD device 100. As shown in FIG. 4A, a plasma CVD process is performed on a predetermined base layer (for example, an Si substrate or a silicon dioxide film) 60 by using N₂/Si₂H₆ plasma. During the plasma CVD process, a process pressure is set to be constant in the range from 10 Pa to 133.3 Pa, and preferably from 20 Pa to 60 Pa. Next, RF power in the range from 0.009 W/cm² to 0.64 W/cm² is supplied from the high frequency power supply 9 to the electrode 7 of the holding stage 2. Therefore, as shown in FIG. 4B, a silicon nitride film 70 may be formed. By applying an RF bias to the base layer 60, a number of traps existing in the silicon nitride film 70 may be increased more uniformly as compared to a case in which no RF bias is applied.

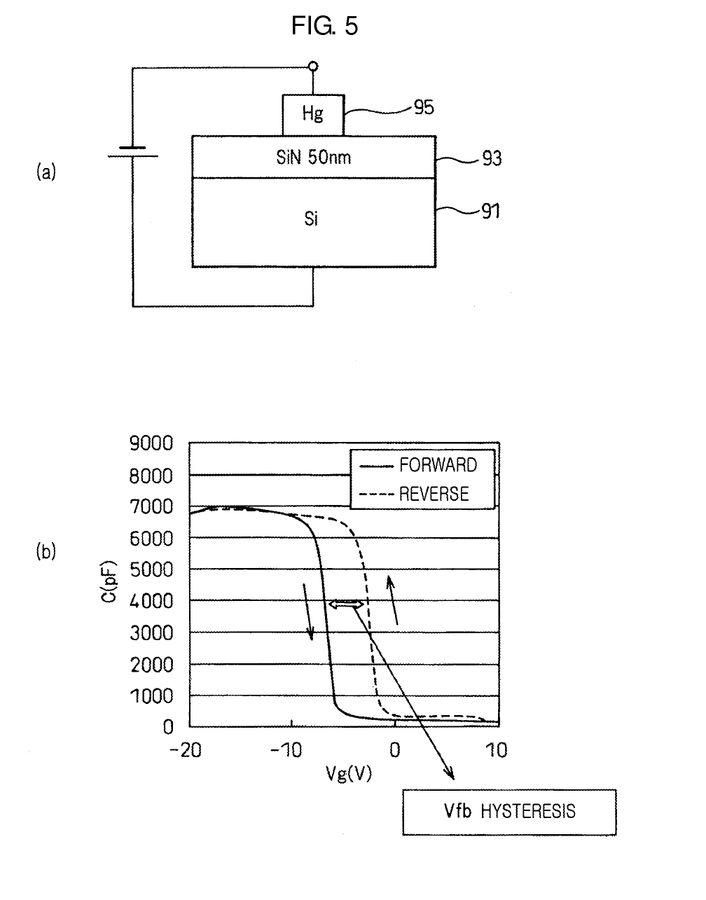

Next, conditions very suitable for the plasma CVD process will be described using experiment data, on which the present invention is based, as an example. Here, a single silicon nitride film was formed in the plasma CVD device 100 by performing plasma CVD under following plasma CVD conditions by using an N₂ gas as the nitrogen containing gas, an Si₂H₆ gas as the silicon containing compound gas, and an Ar gas as a gas for plasma generation. A refractive index, a wet etching rate, and a hysteresis of flat band potential (Vfb) were measured with respect to a silicon nitride film formed under each of following conditions. Furthermore, the hysteresis of Vfb was measured by using an Hg probe method, which is a known method below. First, a test device having a capacitor structure as shown in FIG. 5A was prepared. In FIG. 5A, reference numeral 91 indicates a silicon substrate, reference numeral 93 indicates a silicon nitride film (gate insulation film) formed by using plasma CVD, and reference numeral 95 indicates a mercury gate electrode. Furthermore, by setting the silicon substrate 91 to a ground potential, voltages were variably applied to the mercury gate electrode 95 in the range from −20 V to 10 V (forwarding), and voltages were applied in the reverse direction from 10 V to −20 V (reversing). A capacitance was measured during the reciprocating voltage application, and the Vfb hysteresis was obtained from each CV curve (hysteresis curves) of the forwarding and the reversing, as shown in FIG. 5B. A change of CV curves due to the reciprocating voltage application indicates that, since holes are trapped in a silicon nitride film due to the voltage application, a voltage is changed to eliminate the charges, and that, as the Vfb hysteresis increases, the number of traps in the silicon nitride film also increases.

(Plasma CVD Conditions)

process temperature (holding stage): 400° C.

microwave power: 2 kW (output density 1.023 W/cm², per penetration plate area)

process pressure: 2.7 Pa, 26.6 Pa, 40 Pa

Ar gas flow rate: 600 mL/min (sccm)

N₂ gas flow rate: 400 mL/min (sccm)

Si₂H₆ gas flow rate: 2 mL/min (sccm)

frequency of RF bias: 13.56 MHz

power of RF bias: 0 W, 5 W (output density 0.016 W/cm²), 10 W (output density 0.032 W/cm²), 50 W (output density 0.16 W/cm²)

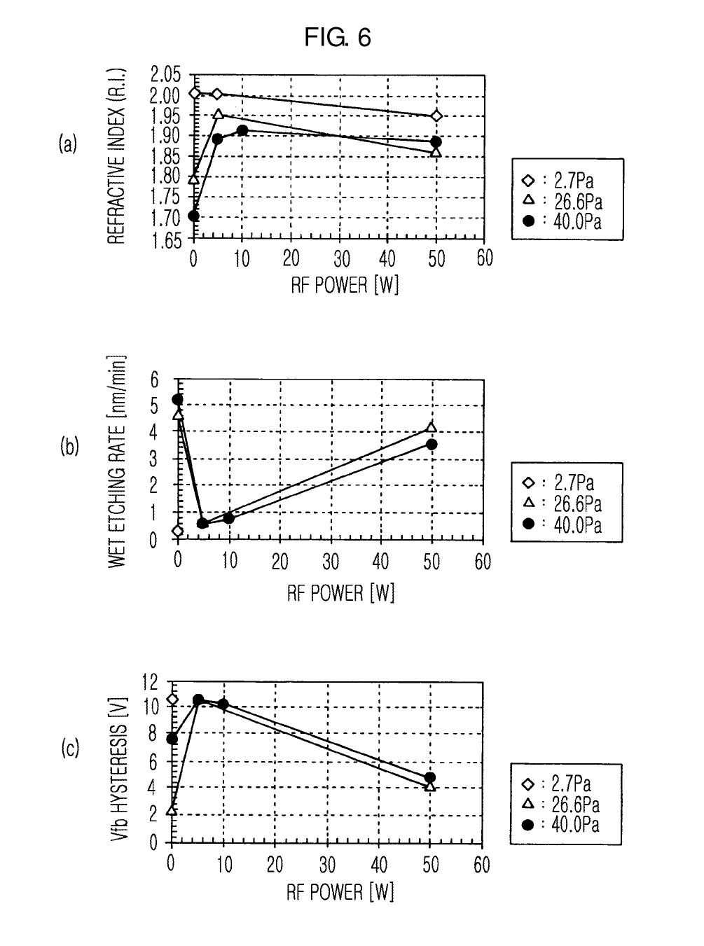

FIG. 6A shows a relationship between refractive indexes of a silicon nitride film and RF bias power supplied to the holding stage 2. FIG. 6B shows a relationship between wet etching rates of a silicon nitride film formed by using dilute hydrofluoric acid and RF bias power supplied to the holding stage 2. FIG. 6C shows a relationship between magnitudes of hysteresis in Vfb measurement of a silicon nitride film and RF bias power supplied to the holding stage 2. From FIG. 6A, in a case where an RF bias is 0.16 W/cm², the refractive indexes are preferably high under process pressures of 2.7 Pa, 26.6 Pa, and 40.0 Pa, being equal to or greater than 1.85. Particularly, under the process pressure of 2.7 Pa, the refractive indexes are preferably high, being equal to or greater than 1.95. Also, in the case where an RF bias is 0.016 W/cm², the refractive indexes are preferably high under process pressures of 2.7 Pa, 26.6 Pa, and 40.0 Pa, being equal to or greater than about 1.90.

From FIGS. 6A through 6C, under process pressures of 26.6 Pa and 40.0 Pa, as RF biases with output densities from about 0.016 W/cm² to about 0.032 W/cm² are applied, the refractive indexes are high, the wet etching rates are low, and the Vfb hysteresis were increased. In terms of increases of the refractive indexes, decreases of the wet etching rates, and increases of the Vfb hysteresis, a variation when RF biases had output densities from 0.016 W/cm² to 0.032 W/cm² with respect to when no RF bias is applied was maximum and the variation was reduced in a case where RF biases with an output density of 0.016 W/cm² were applied. From the results, it is shown that a silicon nitride film that is dense (because of a high refractive index and a low etching rate) and has a large number of traps therein may be formed by applying an RF bias with an output density from about 0.016 W/cm² to about 0.032 W/cm².

The data shown in FIGS. 6A through 6C shows that, by applying an RF bias with an output density in a suitable range, a density of a silicon nitride film may be increased and a number of traps in the silicon nitride film may be uniformly increased. The data may seem to contradict with itself, but reasonable description thereof may be provided by interpreting the data as described below. In plasma CVD, as an RF bias is applied to the wafer W, ions in plasma tend to become more attracted to the wafer W. However, in microwave plasma used in the present invention, an electron temperature may be kept low (from 0.7 eV to 2 eV) even if an RF bias is applied, and thus an electron temperature may also be kept low under a low pressure condition, for example, from 26.6 Pa to 40 Pa. As a result of having a low electron temperature, damages to a film are suppressed, and thus a dense film is formed, and at the same time, ion attraction is controlled by an RF bias. Thus, it is thought that a suitable quantity of traps are formed and uniformly distributed in the film.

Meanwhile, from the results of the refractive indexes and the wet etching rates shown in FIG. 6A and FIG. 6B, it is found that a density of a film decreases even under pressures of 26.6 Pa and 40 Pa in a case where power of an RF bias is too high (e.g., an output density of 0.16 W/cm²). Furthermore, although a silicon nitride film formed by using plasma CVD is basically a dense film, a density of a silicon nitride film decreases if a pressure increases. However, in a case where a fine RF bias (e.g., an output density from 0.016 W/cm² to 0.032 W/cm²) is applied, the density of the silicon nitride film could be increased. In this case, a large number of traps are formed while a density of a film is maintained. However, it is thought that, since a density of a film decreases if an RF bias with an output density of 0.16 W/cm² is applied, Si dangling bonds may be easily terminated, and thus increases in etching rates and decreases in Vfb hysteresis (that is, decreases in a number of traps) are observed as shown in FIGS. 6B and 6C.

From the results above, it is shown that, in a plasma CVD method using the plasma CVD device 100, a silicon nitride film, in which a large number of traps are included and a distribution of the traps is uniformly controlled, may be formed by applying an RF bias with an output density in the range from 0.016 W/cm² to 0.032 W/cm² and setting a process pressure in a range up to 40 Pa (e.g., from 10 Pa to 40 Pa). Furthermore, compared to a case of setting a process pressure to a high vacuum state less than or equal to 3 Pa and performing a plasma CVD process thereunder, the present invention provides advantages of reduced device loads, such as no requirement of a high performance exhauster such as a turbomolecular pump or the like, eased pressure-resistance design standards for the process chamber 1, etc., thereby resulting in cost reduction. Furthermore, in a high vacuum state less than or equal to 3 Pa, due to sputtering of ions or the like, there are process-wise problems, such as exposing the wafer W to a pollution risk due to particles or the like, deterioration of coverage performance in terms of formation of a silicon nitride film, etc. However, such problems may be avoided, because a process pressure may be set high.

Next, in a case where a silicon nitride film is formed by applying an RF bias to an object to be processed in the plasma CVD device 100, effects of a flow rate ratio of Ar with respect to a Vfb hysteresis of the silicon nitride film was reviewed. Under the following conditions, plasma CVD was performed with different Ar flow rates, and a Vfb hysteresis was measured by using the same method as described above.

(Plasma CVD Conditions)

process temperature (holding stage): 400° C.

microwave power: 2 kW (output density 1.023 W/cm², per penetration plate area)

process pressure: 26.6 Pa

Ar gas flow rate: 100 mL/min (sccm), 600 mL/min (sccm), 1100 mL/min (sccm)

N₂ gas flow rate: 400 mL/min (sccm)

Si₂H₆ gas flow rate: 2 mL/min (sccm)

frequency of RF bias: 13.56 MHz

power of RF bias: 5 W (output density 0.016 W/cm²)

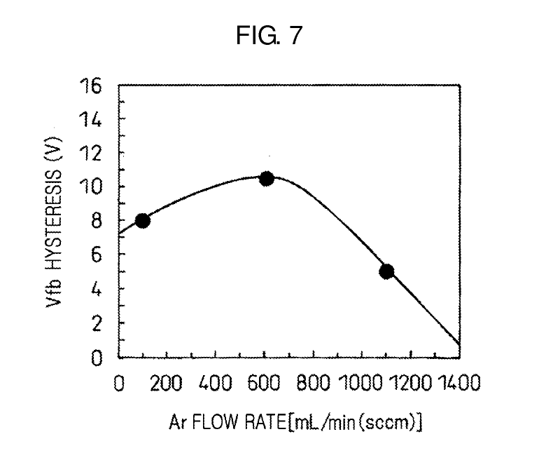

As shown in FIG. 7, if constant RF bias power with an output density of 0.016 W/cm² is applied, a high Vfb hysteresis was observed with respect to Ar gas flow rates of 100 mL/min (sccm) and 600 mL/min (sccm). Also, a low Vfb hysteresis was observed with respect to an Ar gas flow rate of 1100 mL/min (sccm). Therefore, it is thought that an Ar gas flow rate may be in the range from 50 mL/min (sccm) to 1000 mL/min (sccm), and preferably from 100 mL/min (sccm) to 800 mL/min (sccm), in order to increase a Vfb hysteresis.

Furthermore, an Ar gas flow rate ratio with respect to an N₂ gas (Ar/N₂) may be in the range from 0.1 to 3, and, in order to increase a number of traps, may be selected to be in a range up to 2 (e.g., from 0.2 to 2). If the Ar gas flow rate ratio increases, there is an increase in Ar ions in plasma, and thus a Vfb hysteresis decreases. As a result, a number of traps decrease. Furthermore, a flow rate ratio between an Si₂H₆ gas and an Ar gas (Si₂H₆/Ar) may be selected to be in the range from 0.005 to 0.01. Furthermore, the flow rate of the N₂ gas may be set to be in the range from 100 mL/min(sccm) to 1000 mL/min(sccm), and preferably from 100 mL/min(sccm) to 500 mL/min(sccm), whereas the flow rate of the Si₂H₆ gas may be set to be in the range from 0.5 mL/min(sccm) to 40 mL/min(sccm), and preferably from 0.5 mL/min(sccm) to 10 mL/min(sccm).

Also, a process temperature of the plasma CVD process may be set to be such that a temperature of the holding stage 2 is from 300° C. to 600° C., and preferably from 400° C. to 600° C.

Also, a microwave output density in the plasma CVD process as power density per area of the penetration plate 28 through which microwaves penetrate may be in the range from 0.25 W/cm² to 2.56 W/cm².

As described above, in the method for fabricating a silicon nitride film of the present invention, a silicon nitride film having a desired quantity of traps may be easily fabricated on the wafer W by performing plasma CVD by selecting RF bias power and a process pressure. A silicon nitride film having a large number of traps formed as described above may be advantageously used as a charge trapping layer of, for example, an MOS-type semiconductor memory device.

### Second Embodiment

Next, a film formation method for stacking silicon nitride films according to a second embodiment of the present invention will be described. As described above in the first embodiment, in the plasma CVD device 100, a large number of traps may be formed in a formed silicon nitride film with uniform distribution by suitably setting conditions for a plasma CVD process when forming the silicon nitride film, particularly, a magnitude of RF bias power supplied from the high frequency power supply 9 to the electrode 7 of the holding stage 2 and a process pressure. Using this feature, silicon nitride films that are adjacent to each other and have different number of traps therein, for example, may be stacked and formed by switching an RF bias ON/OFF application to a substrate or changing RF bias power.

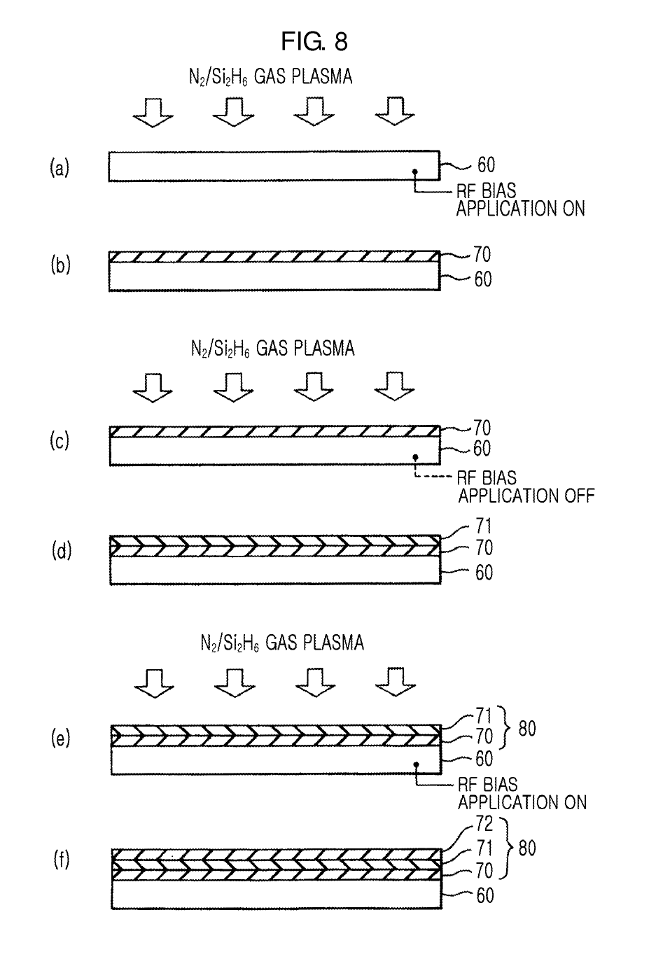

FIG. 8 is a process diagram showing a film formation process for stacking and forming a silicon nitride film performed in the plasma CVD device 100. First, as shown in FIG. 8A, under a pressure in the range from 10 Pa to 133.3 Pa, for example, a plasma CVD process is performed on a predetermined base layer 60 (for example, an Si substrate or a silicon dioxide film) by using plasma formed of a mix of an N₂ gas and an Si₂H₆ gas and applying an RF bias with an output density in the range from 0.009 W/cm² to 0.64 W/cm² (RF bias/ON), and, as shown in FIG. 8B, a first silicon nitride film 70 is formed. The first silicon nitride film 70 includes a plurality of traps therein.

Next, as shown in FIG. 8C, under a pressure in the range from 10 Pa to 133.3 Pa, for example, a plasma CVD process is performed on the first silicon nitride film 70 by using plasma formed of a mix of an N₂ gas and an Si₂H₆ gas without applying an RF bias (RF bias/OFF). As a result, as shown in FIG. 8D, a second silicon nitride film 71 having a second band-gap is formed. The second silicon nitride film 71 is a silicon nitride film having a small number of traps therein as compared to the first silicon nitride film 70. According to the process above, as shown in FIG. 8E, a silicon nitride film stacked structure 80 consisting of 2 layers of silicon nitride films may be formed.

Also, if required, as shown in FIG. 8E, under a pressure in the range from 10 Pa to 133.3 Pa, for example, a plasma CVD process may be performed on the second silicon nitride film 71 by using plasma formed of a mix of an N₂ gas and an Si₂H₆ gas and applying an RF bias with an output density in the range from 0.009 W/cm² to 0.64 W/cm² (RF bias/ON). As a result, as shown in FIG. 8F, a third silicon nitride film 72 may be formed. In this case, a number of traps in the third silicon nitride film 72 may be the same as or different from that of the first silicon nitride film 70. The number of traps in the third silicon nitride film 72 may be controlled according to a magnitude of an applied RF bias.

Then, the silicon nitride film stacked structure 80 having a desired layer structure may be formed by repeatedly performing a plasma CVD process for a required number of times.

As described above, in a film formation method of stacking silicon nitride films according to the present embodiment, under a constant process pressure, numbers of traps in the first silicon nitride film 70, the second silicon nitride film 71, and the third silicon nitride film 72 may be changed according to ON/OFF of an RF bias applied to a base layer. As such, a silicon nitride film may be formed with stacking by depositing silicon nitride films having different numbers of traps on the wafer W by using a film formation gas including a silicon containing compound gas and a nitrogen gas and by switching ON/OFF of an RF bias or changing a magnitude of an RF bias in the range corresponding to that of a fine bias. Particularly, in the film formation method of stacking silicon nitride films according to the present embodiment, under a constant process pressure, a number of traps in each silicon nitride film and a distribution thereof may be sufficiently uniformly controlled only by controlling a fine RF bias, and thus, in a case of forming a stacked structure of silicon nitride films having different numbers of traps therein, film formation may be performed continuously in a same process chamber while maintaining a vacuum state. Therefore, process efficiency is excellent. Therefore, by applying the method of the present invention to formation of a stack of silicon nitride films as a charge trapping region of a MOS-type semiconductor memory device, for example, a MOS-type semiconductor memory device having excellent data writing characteristics may be manufactured.

### Example Applied to Manufacturing of Semiconductor Memory Device

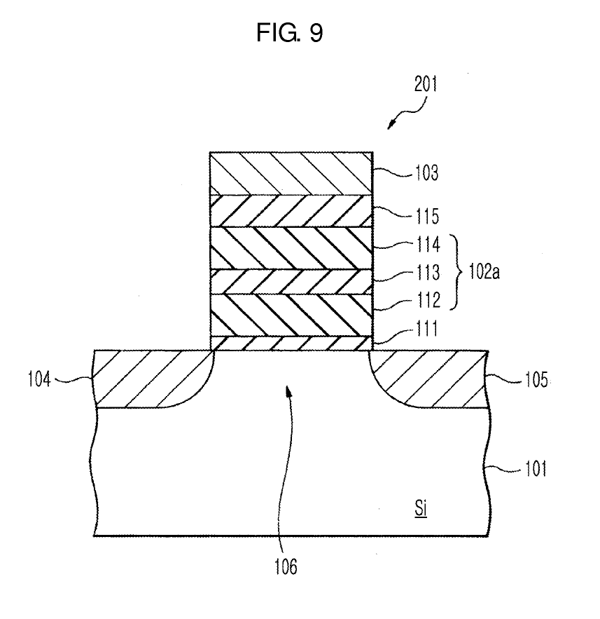

Next, an example of applying the method for fabricating a silicon nitride film according to the present embodiment to a process of manufacturing a semiconductor memory device will be described with reference to FIG. 9. FIG. 9 is a cross-sectional view of a schematic structure of a MOS-type semiconductor memory device 201. The MOS-type semiconductor memory device 201 includes a p-type silicon substrate 101 constituting a semiconductor layer, a plurality of insulation films having different number of traps therein and stacked on the p-type silicon substrate 101, and a gate electrode 103 additionally formed thereon. A first insulation film 111, a second insulation film 112, a third insulation film 113, a fourth insulation film 114, and a fifth insulation film 115 are installed between the silicon substrate 101 and the gate electrode 103. Here, the second, third, and fourth insulation films 112, 113, and 114 are all silicon nitride films, and form a stacked silicon nitride film 102a.

Also, in the silicon substrate 101, first source and drain 104 and second source and drain 105 constituting n-type diffusion layers are formed to be disposed on each side of the gate electrode 103 at a predetermined depth from a surface of the silicon substrate 101, and a channel forming region 106 is formed therebetween. Also, the MOS-type semiconductor memory device 201 may be formed on a p-well or a p-type silicon layer formed inside a semiconductor substrate. Also, the present embodiment is explained using an n-channel MOS device as an example, but a p-channel MOS device may be used. Accordingly, descriptions of the present embodiment hereinafter may be applied both to an n-channel MOS device and a p-channel MOS device.

The first insulation film 111 is a silicon dioxide film (SiO₂ film) formed by oxidizing a surface of the silicon substrate 101 by using thermal oxidation, for example. A film thickness of the first insulation film 111 may be, for example, in the range from 0.5 nm to 20 nm, and preferably in the range from 1 nm to 3 nm.

The second insulation film 112 forming the stacked silicon nitride film 102a is a silicon nitride film (SiN film; here, a composition ratio of Si and N is not definitely determined stoichiometrically, but has different values according to film formation conditions. The same is applied hereinafter) formed on a surface of the first insulation film 111. A film thickness of the second insulation film 112 may be, for example, in the range from 2 nm to 20 nm, and preferably in the range from 3 nm to 5 nm.

The third insulation film 113 is a silicon nitride film (SiN film) formed on the second insulation film 112. A film thickness of the third insulation film 113 may be, for example, in the range from 2 nm to 30 nm, and preferably in the range from 4 nm to 10 nm.

The fourth insulation film 114 is a silicon nitride film (SiN film) formed on the third insulation film 113. The fourth insulation film 114 may, for example, have the same number of traps therein and the same film thickness as the second insulation film 112.

The fifth insulation film 115 is a silicon dioxide film (SiO₂ film) deposited on the fourth insulation film 114, for example, via a CVD method. The fifth insulation film 115 operates as a block layer (barrier layer) between the gate electrode 103 and the fourth insulation film 114. A film thickness of the fifth insulation film 115 may be, for example, in the range from 2 nm to 30 nm, and preferably in the range from 5 nm to 8 nm.

Also, a poly-silicon layer may be formed between the first insulation film 111 and the second insulation film 112 as a floating gate electrode.

The gate electrode 103 is, for example, composed of a polycrystalline silicon film formed by a CVD method, and operates as a control gate (CG) electrode. Alternatively, the gate electrode 103 may be a layer including a metal such as W, Ti, Ta, Cu, Al, Au, Pt, or the like. The gate electrode 103 is not limited to a single layer, and may have a stacked structure including, for example, tungsten, molybdenum, tantalum, titan, platinum, a silicide thereof, a nitride thereof, an alloy thereof, etc., so as to increase an operating speed of the MOS-type semiconductor memory device 201 by reducing a specific resistance of the gate electrode 103. The gate electrode 103 is connected to a wire layer (not shown).

Also, in the MOS-type semiconductor memory device 201, the stacked silicon nitride film 102a formed by the second, third, and fourth insulation films 112, 113, and 114 is a charge accumulating region that mainly accumulates charges. Therefore, data writing performance or data holding performance of the MOS type semiconductor memory device 201 may be controlled by applying the method of forming a silicon nitride film according to the first embodiment of the present invention and controlling a number of traps in each film and a distribution thereof during formations of the second insulation film 112, the third insulation film 113, and the fourth insulation film 114. Furthermore, the second insulation film 112, the third insulation film 113, and the fourth insulation film 114 may be continuously fabricated in a same process chamber by applying the method of forming a stacked silicon nitride film according to the second embodiment of the present invention, maintaining a constant process pressure in the plasma CVD device 100, and switching ON/OFF of a RF bias or changing a magnitude of the RF bias.

The example of applying the method of the present invention to the manufacturing of the MOS-type semiconductor memory device 201 will be described using main procedures as an example. First, the silicon substrate 101 on which an isolation film (not shown) is formed using a method such as a LOCOS (Local Oxidation of Silicon) method, an STI (Shallow Trench Isolation) method or the like is prepared, and the first insulation film 111 is formed on a surface of the silicon substrate 101 by using a thermal oxidation method, for example.

Next, the second, third, and fourth insulation films 112, 113, and 114 are sequentially formed on the first insulation film 111 by using a plasma CVD method.

In a case of forming the second insulation film 112, a process pressure is set in the range from 10 Pa to 133.3 Pa, and RF power with an output density in the range from 0.009 W/cm² to 0.64 W/cm² per unit area of the wafer (W) is supplied to the electrode 7 of the holding stage 2. As such, film formation is performed by applying an RF bias to the silicon substrate 101, such that a large number of traps are formed therein with uniform distribution. When forming the third insulation film 113, plasma CVD is performed without applying an RF bias to the silicon substrate 101, such that the number of traps therein is smaller than the second insulation film 112. When forming the fourth insulation film 114, plasma CVD is performed under a film forming condition different from the film formation condition for forming the third insulation film 113 (for example, applying the same RF bias to the silicon substrate 101 as in the case of forming the second insulation film 112), such that a number of traps therein is greater than the third insulation film 113. As described above, a number of traps in each film may be controlled by maintaining a constant process pressure for a plasma CVD process and by switching ON/OFF of a RF bias or changing a magnitude of the RF bias.

Next, the fifth insulation film 115 is formed on the fourth insulation film 114. The fifth insulation film 115 may be formed, for example, by using a CVD method. Also, a metal film constituting the gate electrode 103 is formed on the fifth insulation film 115, by forming a polysilicon layer, a metal layer, a metal silicide layer, or the like by using, for example, a CVD method.

Then, the metal film and the fifth through first insulation films 115 through 111 are etched by using a patterned resist as a mask using a photolithography technology, thereby obtaining a gate stacked structure having the patterned gate electrode 103 and the plurality of insulation films. Next, a high concentration of n-type impurities are ion-injected into a silicon surface adjacent to both sides of the gate stacked structure, thereby forming the first source and drain 104 and the second source and drain 105. As such, the MOS-type semiconductor memory device 201 having the structure of FIG. 9 may be manufactured.

Also, although numbers of traps in the second insulation film 112 and the fourth insulation film 114 are greater than a number of traps in the third insulation film 113 in the stacked silicon nitride film 102a in the example above, the number of traps in the third insulation film 113 may be greater than the numbers of traps in the second insulation film 112 and the fourth insulation film 114. Also, numbers of traps in the second insulation film 112 and the fourth insulation film 114 do not have to be the same.

Also in FIG. 9, the stacked silicon nitride film 102a is formed of three layers, i.e., the second through fourth insulation films 112 through 114, but the method of the present invention may also be applied to cases of manufacturing an MOS-type semiconductor memory device having a silicon nitride film structure in which two or four or more silicon nitride films are stacked.

The embodiments of the present invention have been described above, but the present invention is not limited to the above embodiments, and may vary. For example, although cases of using a nitrogen gas and disilane as raw gases for film formation are described in the example embodiments above, ammonia, hydrazine, monohydrazine, or the like may be used, aside from a nitrogen gas. Also, it is possible to control a number of traps in a silicon nitride film and a distribution thereof uniformly by applying an RF bias to a substrate even in a case of using another silicon containing compound gas, e.g., silane, trisilane, trisilylamine, or the like.

### EXPLANATION OF REFERENCE NUMERALS

1: process chamber
2: holding stage
3: supporting member
5: heater
9: high frequency power supply
12: exhaust pipe
14: first gas introduction unit
15: second gas introduction unit
16: transfer hole
17: gate valve
18: gas supply apparatus
19a: nitrogen containing gas supply source
19b: silicon containing compound gas supply source
19c: inert gas supply source
19d: cleaning gas supply source
24: exhauster
27: microwave introduction apparatus
28: penetration plate
29: seal member
31: planar antenna
32: microwave radiation hole
37: waveguide
39: microwave generator
50: control unit
100: plasma CVD device
101: silicon substrate
102a: stacked silicon nitride film
103: gate electrode
104: first source and drain
105: second source and drain
111: first insulation film
112: second insulation film
113: third insulation film
114: fourth insulation film
115: fifth insulation film
201: MOS-type semiconductor memory device
W: silicon wafer (substrate)

1. A method for depositing a silicon nitride film on an object to be processed by using a plasma CVD method by using a plasma CVD device that generates plasma by introducing microwaves into a process chamber by using a planar antenna having a plurality of apertures, the method comprising forming a silicon nitride film by setting a pressure inside the process chamber in a range from 10 Pa to 133.3 Pa and by performing plasma CVD by using film formation gases including a silicon containing compound gas and a N₂ gas while applying a high frequency bias to the object to be processed by supplying high frequency power with an output density in a range from 0.009 W/cm² to 0.64 W/cm² per unit area of the object to be processed to an electrode of a holding stage, on which the object to be processed is arranged, wherein a flow rate ratio of an Ar gas to the silicon containing compound gas is in a range from 0.005 to 0.01, and a ratio of a flow rate of the Ar gas to the N₂ gas is in a range from 0.1 to 3.

2. A method for depositing a silicon nitride film by stacking silicon nitride films on an object to be processed by using a plasma CVD method by using a plasma CVD device that generates plasma by introducing microwaves into a process chamber by using a planar antenna having a plurality of apertures, the method comprising:
a first operation for forming a silicon nitride film by setting a pressure inside the process chamber in a range from 10 Pa to 133.3 Pa, and performing plasma CVD by using film formation gases including a silicon containing compound gas and a N₂ gas while applying a high frequency bias to the object to be processed by supplying high frequency power with an output density in a range from 0.009 W/cm² to 0.64 W/cm² per unit area of the object to be processed to an electrode of a holding stage, on which the object to be processed is arranged; and
a second operation for forming a silicon nitride film that has a small number of traps as compared to the silicon nitride film formed in the first operation, under the same set pressure as the first operation, by performing plasma CVD by using film formation gases including a silicon containing compound gas and a N₂ gas by not applying high frequency power to the electrode of the holding stage or by applying a high frequency bias to the object to be processed by supplying high frequency power with an output density different from the output density of the first operation.

3. The method for depositing the silicon nitride film of claim 2, wherein the first operation and the second operation are repeatedly performed.

4. A computer-readable storage medium having recorded thereon a control program to be operated on a computer, wherein, when a silicon nitride film is being formed on an object to be processed by using a plasma CVD method by using a plasma CVD device that generates plasma by introducing microwaves into a process chamber by using a planar antenna having a plurality of apertures, the control program enables the computer to control the plasma CVD device to perform plasma CVD by using film formation gases including a silicon containing compound gas and a N₂ gas under a process pressure in a range from 10 Pa to 133.3 Pa by applying high frequency bias to the object to be processed by supplying high frequency power with an output density in a range from 0.009 W/cm² to 0.64 W/cm² per unit area of the object to be processed to an electrode of a holding stage, on which the object to be processed is arranged, wherein a flow rate ratio of an Ar gas to the silicon containing compound gas is in a range from 0.005 to 0.01, and a ratio of a flow rate of the Ar gas to the N₂ gas is in a range from 0.1 to 3.

5. A plasma CVD device that forms a silicon nitride film on an object to be processed by using a plasma CVD method, the plasma CVD device comprising:
a process chamber that accommodates the object to be processed and has an opening on a top of the process chamber;
a holding stage that is arranged inside the process chamber and on which the object to be processed is arranged;
an electrode that is installed in the holding stage and applies high frequency power to the object to be processed;
a high frequency power supply connected to the electrode;
a dielectric member that closes the opening of the process chamber;
a planar antenna that is installed on the dielectric member and has a plurality of apertures for introducing microwaves into the process chamber;
a gas introduction unit that is connected to a gas supply apparatus for supplying a film formation gases including a silicon containing compound gas and a N₂ gas into the process chamber;
an exhauster that depressurizes and exhausts an inside of the process chamber; and
a control unit that controls plasma CVD to be performed in the process chamber under a process pressure in a range from 10 Pa to 133.3 Pa by supplying the film formation gases including the silicon containing compound gas and the N₂ gas into the process chamber while applying a high frequency bias to the object to be processed by supplying high frequency power with an output density in a range from 0.009 W/cm² to 0.64 W/cm² per unit area of the object to be processed from the high frequency power supply to the electrode, wherein a flow rate ratio of an Ar gas to the silicon containing compound gas is in a range from 0.005 to 0.01, and a ratio of a flow rate of the Ar gas to the N₂ gas is in a range from 0.1 to 3.

6. A plasma CVD device that stack-forms a silicon nitride film on an object to be processed by using a plasma CVD method, the plasma CVD device comprising:
a process chamber that accommodates the object to be processed and has an opening on a top of the process chamber;
a holding stage that is arranged inside the process chamber and on which the object to be processed is arranged;
an electrode that is installed in the holding stage and applies high frequency power to the object to be processed;
a high frequency power supply connected to the electrode;
a dielectric member that closes the opening of the process chamber;
a planar antenna that is installed on the dielectric member and has a plurality of apertures for introducing microwaves into the process chamber;
a gas introduction unit that is connected to a gas supply apparatus for supplying film formation gases including a silicon containing compound gas and an N₂ gas into the process chamber;
an exhauster that depressurizes and exhausts an inside of the process chamber; and
a control unit that controls plasma CVD to be performed in the process chamber under a process pressure in a range from 10 Pa to 133.3 Pa by supplying the film formation gases including the silicon containing compound gas and the N₂ gas into the process chamber while not applying a high frequency bias to the object to be processed or applying a high frequency bias to the object to be processed by supplying high frequency power with an output density in a range from 0.009 W/cm² to 0.64 W/cm² per unit area of the object to be processed from the high frequency power supply to the electrode, wherein a flow rate ratio of an Ar gas to the silicon containing compound gas is in a range from 0.005 to 0.01, a ratio of a flow rate of the Ar gas to the N₂ gas is in a range from 0.1 to 3,
wherein a plurality of silicon nitride films having different numbers of traps therein are formed by changing output density per unit area of the object to be processed.

7. A semiconductor memory device comprising:
a first insulation film formed on a semiconductor substrate;
stacked silicon nitride films formed on the first insulation film;
a second insulation film formed on the stacked silicon nitride films; and
a gate electrode formed on the second insulation film,
wherein the stacked silicon nitride films comprises at least a first silicon nitride film and a second silicon nitride film that are continuously formed in a same plasma CVD device, and
the second silicon nitride film formed on the first silicon nitride film is a silicon nitride film having a smaller number of traps therein as compared to the first silicon nitride film formed on the first insulation film.
